(19) United States
(12) Patent Application Publication
(10) Pub. No.: US 2007/0235844 A1
(43) Pub. Date: Oct. 11, 2007

(54) ELECTRONIC DEVICE MOUNTING STRUCTURE AND METHOD OF MANUFACTURING THE SAME

(75) Inventor: Hiroki Suzuki, Fukushima-ken (JP)

Correspondence Address: BRINKS HOFER GILSON & LIONE, P.O. BOX 10395, CHICAGO, IL, 60610, US

(73) Assignee: ALPS ELECTRIC CO., LTD., Tokyo (JP)

(21) Appl. No.: 11/697,196

(22) Filed: Apr. 5, 2007

(30) Foreign Application Priority Data
Apr. 6, 2006 (JP) 2006-105249

(51) Int. Cl. H01L 23/495

(52) U.S. Cl. 257/668

(57) ABSTRACT

A mounting structure of an electronic device capable of properly enhancing a bonding strength between an insulating substrate and the electronic device is provided. An electrode and an earth electrode having a surrounding shape are formed on an insulating substrate. In addition, a non-metal area exposing a surface of the insulating substrate is provided in the surrounding shape. An earth terminal is provided on a position opposed to the non-metal area on a back surface of an electronic device. The non-metal area and the earth terminal are bonded to each other by a solder adhesive including solder particles and a resin as major components. The solder particles are agglomerated on the earth terminal, then a solder layer is formed, and the earth terminal and the non-metal area are bonded to each other by the resin layer. Accordingly, a bonding strength between the electronic device and the insulating substrate are properly enhanced.

### CROSS-REFERENCE TO RELATED APPLICATIONS

This application claims the benefit of priority under 35 U.S.C. §119 to Japanese Patent Application No. 2006-105249 filed on Apr. 6, 2006, which is hereby incorporated by reference in its entirety.

### BACKGROUND OF THE INVENTION

1. Field of the Invention

This invention relates to an electronic device mounting structure capable for enhancing a bonding strength between an insulating substrate and the electronic device, and a method of manufacturing the electronic device mounting structure.

2. Description of the Related Art

An electronic device mounting structure which mounts an electronic device on an insulating substrate is disclosed in Japanese Unexamined Patent Application Publication No. 2003-309353.

An electronic is provided at a position opposite a terminal of the electronic device on a front surface of the insulating substrate, and the electrode and the terminal are soldered to each other.

The electrode is formed on the insulating substrate by a screen print. For example, the electrode is formed of Ag coated film, and a content of binder resin is adjusted to have a low content so as to enhance solder wettability. Accordingly, a bonding strength between the electrode and the insulating substrate may be decreased.

Accordingly, although the electrode and the terminal are properly solder, the electronic device might be separated from the insulating substrate by accompanying the electrode. Accordingly, it is necessary at the bonding strength between the electronic device and the insulating is greatly increased. An example of such an invention is disclosed in Japanese Unexamined Patent Application Publication No. 2003-309353.

### SUMMARY OF THE INVENTION

In the invention disclosed in Japanese Unexamined Patent Application Publication No. 2003-309353, an insulating layer having a rib-shape is provided on an insulating substrate so as to provide a resin layer (adhesive) in a space between the insulating substrate and an electronic device, which is generated by a formation of the insulating layer.

However, in Japanese Unexamined Patent Application Publication No. 2003-309353, when the insulating layer has a difference of a height, the insulating substrate and the electronic device are not properly bonded, and bonding strength may be reduced.

In addition, in the invention disclosed in Japanese Unexamined Patent Application Publication No. 2003-309353, since an applying process of solder formed on the insulating substrate to an electrode and an applying process of an adhesive on the insulating substrate are performed respectively, a manufacturing process is complex.

Accordingly, the invention solves the above-mentioned problem. Specifically, it is an object of the present invention to provide a mounting structure of an electronic device capable of enhancing a bonding strength between an insulating substrate and the electronic device, and a method of manufacturing the mounting structure of the electronic device.

According to an aspect of the invention, there is provided an electronic device mounting structure including an insulating substrate having an electrode provided on a front surface thereof, and an electronic device having a terminal connect electrically to the electrode. A first metal area is formed at a position on one opposed surface of the insulating substrate and the electronic device opposed to a non-metal area on the other opposed surface, and the first metal area and the non-metal area are bonded to each other by a solder adhesive containing solder particles and a resin as major components. The solder particles are agglomerated on the first metal area so as to form a solder layer, and the resin bonds the first metal area and the non-metal area to each other.

In the invention, as mentioned above, since the insulating substrate and the electric device are properly bonded by using the solder adhesive, a bonding strength between the insulating substrate and the electronic device may be increased. In the invention, the solder particle is agglomerated to the first metal area by providing the first metal area. Accordingly, the solder particle may be prevented from being attached at undesired locations.

In the invention, the electrode and the terminal may be soldered using the same solder adhesive used for bonding the first metal area and the non-metal area to each other. Accordingly, a bonding strength between the insulating substrate and the electronic device may be increased.

In addition, in the invention, a second metal area is formed in a part of an area on the front surface of the insulating substrate opposed to the first metal area formed on the back surface of the electronic device. The front surface of the insulating substrate as the non-metal area is exposed from the other opposed area, and the first metal area and the second metal area are soldered using the same adhesive used for bonding the first metal area and the front surface of the insulating substrate. Accordingly, the bonding strength between the insulating substrate and the electronic device may be increased.

In addition, the second metal area has a surrounding shape, the front surface of the insulating substrate as the non-metal area is exposed in tie surrounding shape, and the front surface of the insulating substrate in the surrounding shape and the first metal area are bonded to each other by the solder adhesive. Accordingly, as mentioned above, the degradation of an alignment in precision of the electronic device about the insulating substrate may be decreased.

According to an another aspect of the invention, a method of manufacturing an electronic device mounting structure includes an insulting substrate having an electrode provided on a front surface thereof, and an electronic device having a terminal electrically connected to the electrode in which the electronic device is mounted on the insulating substrate. A first metal area is formed at a position on one opposed surface of the insulating substrate and the electronic device opposed to a non-metal area on the other opposed surface, wherein the electrode and the terminal are soldered by a solder adhesive containing solder particles. A resin as major components and being the same as the solder adhesive, and wherein the non-metal area and the first metal area are bonded to each other by the resin contained in the solder adhesive by the use of the same process as bonding the electrode and the terminal.

Because a metal area of the electrode, the terminal, the non-metal area, and the first metal area are bonded by the same solder adhesive, an applying process of each solder adhesive and the heating process (refer to the two process as a bonding process) are performed in same process. Accordingly, by using a simple manufacturing method, the insulating and the electronic device are strongly bonded.

In addition, the resin is a thermosetting resin, the solder adhesive is applied and heated to melt the solder particles, the electrode and the terminal are soldered, and the resin is thermally cured to bond the non-metal area and the first metal area to each other.

In addition, the first metal area may be formed in a back surface of the electronic device, the front surface of the insulating substrate is the non-metal area, the solder adhesive is applied onto the electrode and the front surface of the insulating substrate, and then the electronic device is bonded to the insulating substrate with the solder adhesive. Accordingly, the insulating substrate and the electronic device are strongly bonded.

In addition, a second metal area may be formed in a part of the area on the front surface of the insulating substrate opposed to the first metal area formed on the back surface of the electronic device. The front surface of the insulating substrate as the non-metal area is opposed from the other opposed area, the solder adhesive is applied onto the electrode, the second metal area, and the front surface of the insulating substrate, and then the electronic device is bonded onto the insulating substrate with the solder adhesive. Accordingly, the second metal area has a surrounding shape, the front surface of the insulating substrate as the non-metal area is exposed in the surrounding shape, and the front surface of the insulating substrate and the first metal area are bonded to each other in the surrounding shape by the solder adhesive. According, the degradation of an alignment in precision of the electronic device about the insulating substrate may be reduced.

### BRIEF DESCRIPTION OF THE DRAWINGS

FIG. 1 is a mounting structure of the electronic device according to an embodiment.

FIG. 2 is a sectional view illustrating the structure of the electronic device as viewed from a direction taken along Line 2-2 shown in FIG. 1.

FIG. 3 is a back view of the electronic device.

FIGS. 4A and 5A are a top plan view illustrating the insulating substrate in a process of manufacturing. FIG. 4B is a cross sectional view illustrating the insulating substrate of FIG. 4A taken along Line 4B-4B by cutting in a thickness direction as viewed from an arrow direction.

FIG. 5B is a cross sectional view illustrating the insulating substrate of FIG. 5A taken along Line 5B-5B by cutting in a thickness direction.

According to the invention, the insulating substrate and the electronic device are properly bonded by using the solder adhesive. Accordingly, a bonding strength between the insulating substrate and the electronic device may be enhanced.

### DESCRIPTION OF THE PREFERRED EMBODIMENT

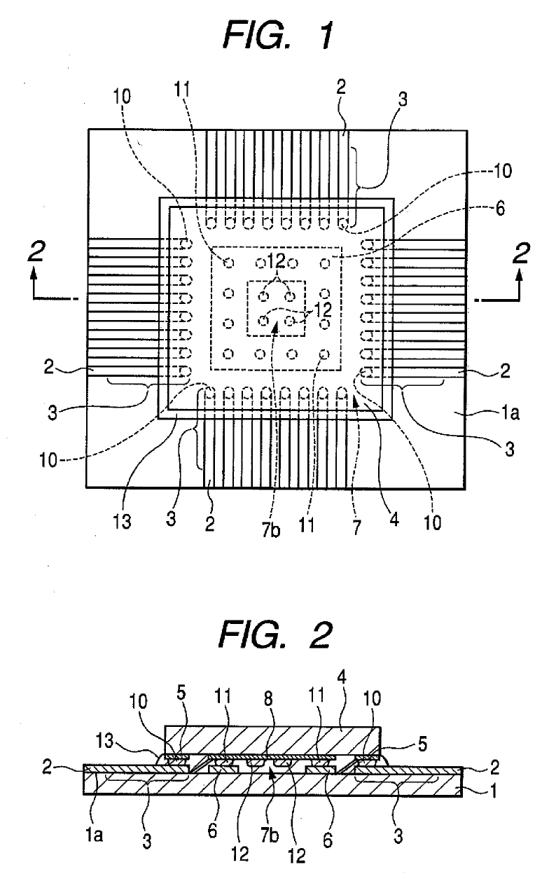

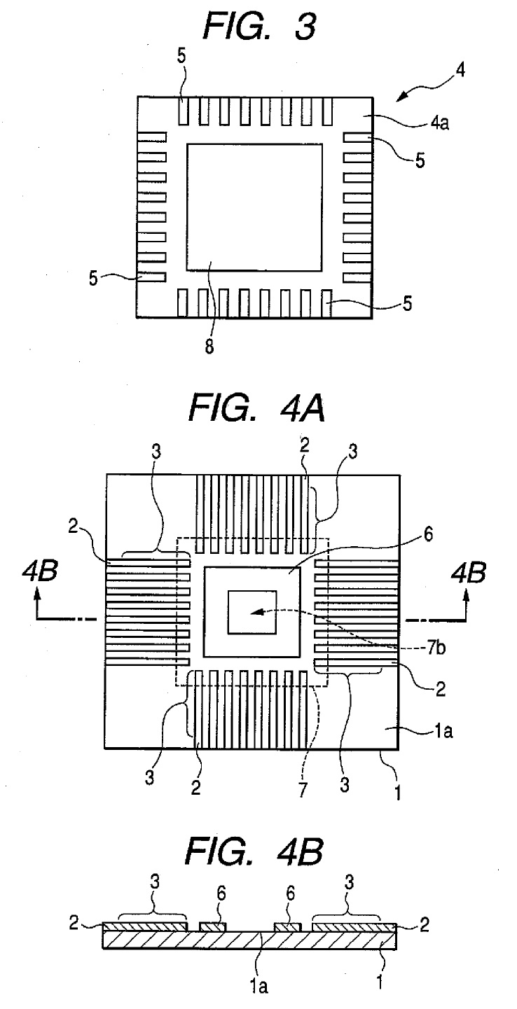

FIG. 1 is a top plan view illustrating a mounting structure of an electronic device according to an embodiment. FIG. 2 is a sectional view illustrating the structure of the electronic device as viewed from a direction taken along Line 2-2 shown in FIG. 1 by cutting in a height direction (thickness direction). FIG. 3 is a back view of the electronic device.

Reference numeral 1 shown in FIGS. 1 and 2 denotes an insulating substrate. Since the insulating substrate 1 can be manufactured at low cost, the insulating substrate 1 is suitable for polyethylene terephthalate (PET) film. However, the PET film has a low heat resistance. Accordingly, when high flame resistance is needed greater than that of the PET on the insulating substrate 1, polyimide (PI) film may be used. In addition, in the embodiment, since a low melting-point solder is used, it is possible to use the PET film on the insulating substrate 1. In addition, when high transparency is required by the insulating substrate 1, polyethylene naphthalate film (PEN) may be used.

A plurality of wiring members 2 is directly formed on a surface 1a of the insulating substrate 1 with a pattern (the reference numeral is attached to a few number of wiring members 2 among a plurality of wiring members 2 in FIG. 1).

An electrode 3 is connected to a leading end (a position opposed to with an electronic device 4 in a height direction) of the wiring member 2 (reference numeral is attached to a few number of electrode 3 among a plurality of electrodes 3 in FIG. 1).

A good wettability is required differently from the wiring member 2 in the electrode 3. Meanwhile, the wiring member 2 is required to have a low electric resistance and an excellent printability. The electrode 3 and the wiring member 2 may form a whole pattern by using the same material. However, since the required characteristic is different, it is desirable that the electrode 3 and the wiring member 2 are formed with different material so as to satisfy the required characteristic.

In the embodiment, the content of resin component contained in the electrode 3 is smaller hand the content contained in the wiring member 2. It is desirable that amount of metal powder included in the electrode 3 is in the range of 90 mass % to 97.5 mass % among all solid components. It is desirable that the metal powder contained in the wiring member 2 and the electrode 3 is a silver powder. Herein, the wiring member 2 and the electrode 3 include silver powder having a shape, such as a rectangular-shape, an infinite form, and a flake-shape with mixing or without mixing. The electrode 3 may include silver powder of the flake-shape. When the silver powder of the flake-shape is included in the electrode 3, a part of the solder easily moves the silver powder of the flake-shape and enters inside of the electrode 3 by bonding a terminal 5 between the electrode 3 and the electronic device 4. As a result, it is possible to strongly bond the electrode 3 and the terminal 5. In addition, the metal powder may be formed from other than silver powder. For example, metal-plated bronze powder, silver-coated bronze powder, silver/bronze alloy powder, metal-plated nickel powder, silver-coated nickel powder, and silver/nickel alloy powder may be used.

As mentioned above, a content of binder resin contained in the electrode 3 is less than that of the wiring member 2. Accordingly, a bonding strength between the electrode 3 and the insulating substrate 1 is less than a bonding strength between the wiring member 2 and the insulating substrate 1.

The thermosetting resin and thermoplastic resin are all used in the binder resin contained in the electrode 3. For example, the binder resin is polyester resin.

As shown in FIGS. 1 and 2, the electrode 3 is formed in the vicinity of mounting area 7 of the electronic device 4 provided on the insulating substrate 1. A formation position of each electrode 3 is in a position opposite each terminal 5 formed in the electronic device 4. In addition, an earth electrode 6 (second metal area) forms a surrounding shape on the insulating substrate 1 in the mounting area 7. It is desirable that the earth electrode 6 is made of the same material as the electrode 3 and is formed with a pattern by using the same process of the electrode 3, such as a screen print. The earth electrode 6 is electrically connected to the wiring member 2, which is not denoted. In addition, a part of the electrode 3 may be the earth electrode with the earth electrode 6.

The shape of the earth electrode 6 is not limited. However, it is desirable to have the surrounding shape as shown in FIG. 1. A non-metal area 7b having a front surface of the insulating substrate 1 is exposed in a center of the mounting area 7 by forming the earth electrode 6 into the surrounding shape.

The electronic device 4 is a QFN (Quad Flat Non-Leaded package) type electronic device. That is, the electronic device is a surface mounting type electronic device in which a terminal pin is not externally exposed. As shown in FIG. 3, a terminal 5 is provided in a position opposite to the electrode 3 at a back surface 4a of the electronic device 4 (the reference numerals are attached to some of the terminals). In addition, an earth terminal 8 (first metal area) is formed in a center portion of the back surface 4a.

In the embodiment shown in FIG. 1, a shape of the earth electrode 6 has the same shape as that of the earth terminal 8, but the size maybe different. However, in a plan view, the earth terminal 8 may be formed having a size at least including a part of the earth electrode 6 and the non-metal area 7b. In other words, in the plan view, a size and a shape of the earth electrode 6 are limited so that the earth terminal 8 includes at least a part of the earth electrode 6 and the non-metal area 7b.

The terminal 5 and the earth terminal 8 is formed of metal material by using a plating method, and the like. For example, the terminal 5 and the earth terminal 8 are formed of Sn plating, but the material may be different.

In FIG. 1 circular dotted-line portions denote solder layers 10, 11, 12. As shown in FIGS. 1 and 2, the electrode 3 on the insulating substrate 1 and the terminal 5 of the electronic device 4 are electrically connected than the solder layer 10 (reference numeral is attached to a part of the solder layer 10).

In addition, the earth electrode 6 and the earth terminal 8 are electrically connected by the solder layer 11.

Accordingly, as shown in FIG. 2, the solder layer 12 is formed in contact with the earth terminal 8 between the non-metal area 7b and the earth terminal 8, and the solder layer 12 is separated from on the non-metal area 7b. As mentioned above, in the embodiment, the solder particle is not agglomerated on the non-metal area 7b, the solder particle is agglomerated on the earth terminal 8 side which is metal, and the solder layer 12 is then formed.

In the embodiment shown in FIGS. 1 and 2, the solder layers 10, 11, 12 are all formed of the same material. The solder layers 10, 11, 12 use a low melting-point solder. The low melting-point solder is SnBi, SnBiAg, SnZn, SnZnBi, SnZnIn, SnAgBiIn, SnAgCuBi, SnIn, SnBiIn, and so on. In addition, the alloys may include a small quantity of heterogeneous metal, such as Al, Ag, Cu, Ge, Ni so as to enhance the metal structure of the alloy, the wettability of the alloy, and prevent surface of oxidation at the time of melting. Herein, “a low melting-point solder” is a solder having a melting-point in the range of 60° C. to 200° C.

In addition, a general type of soldering is tat bonding material and solder forms an alloy, but in the embodiment, the general soldering includes a physical bonding. In addition, in the embodiment, agglomeration of the solder particle is a phenomenon where the solder particle is melted by the heat treatment and then the solder particles form a lump.

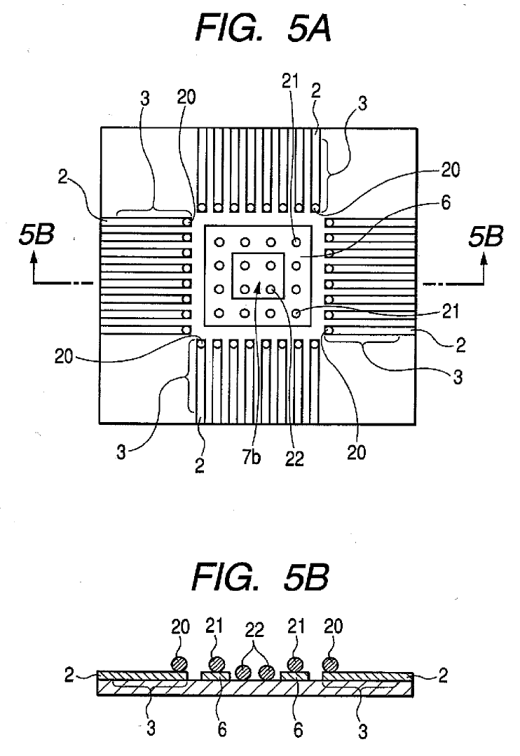

As shown in FIGS. 1 and 2, a resin layer 13 is increased at a gap (gap other than a formation area of the solder layers 10, 11, 12) provided between the electronic device 4 and the insulating substrate 1, and the resin layer 13 is increased around the electronic device 4. The resin layer 13 is formed by resin included in (1) a solder adhesive 20 (refer to FIG. 5) used for bonding the electrode 3 and the terminal 5, (2) resin included in a solder adhesive 21 (refer to FIG. 5) used for bonding the earth electrode 6 and the earth terminal 8, and (3) resin included in a solder adhesive 22 (refer to FIG. 5) used for bonding the surface 1a of the insulating substrate 1 on the non-metal area 7b and the earth terminal 8. The resin is divided from the solder particle by the heat treatment and forms the resin 13 shown in FIGS. 1 and 2.

Herein, a bonding structure between the electronic device 4 and the insulating substrate 1 is the structure between the non-metal area 7b and the earth terminal 8. As shown in FIG. 2, the solder layer 12 is formed in contact with the earth terminal 8, and the resin layer 13 is bonded between the surface 1a of the insulating substrate 1, which is the non-metal area 7b and the earth terminal 8. When the solder adhesive 20 (refer to FIG. 5) used for bonding the electrode 3 and the terminal 5, and the solder adhesive 21 (refer to FIG. 5) used for bonding the ear& electrode 6 and the earth terminal 8 are only used, the non-metal area 7b and the earth terminal 8 have a gap, and the bonding strength between the insulating substrate 1 and the electronic device 4 is substantial (following comparative example is the above mentioned structure).

That is, as mentioned above, the bonding strength between the electrode 3, the earth electrode 6 and the insulating substrate is not substantially high. Accordingly, although the bonding strength between the electrode 3, the earth electrode 6, and the electronic device 4 is increased by using the solder adhesive, the electrode 3 and the earth electrode 6 may be easily separated from the front surface of the insulating substrate 1. The electronic device 4, the electrode 3, and the earth electrode 6 might be separated from the insulating substrate 1 at this time. Meanwhile, in the embodiment by using the non-metal area 7b, the front surface of the insulating substrate 1, which is the non-metal area 7b, and the electronic device 4 are bonded to each other by the resin layer 13. Accordingly, it is possible to enhance the bonding strength between the electronic device 4 and the insulating substrate 1. In other words, in the embodiment, since the bonding strength between the electronic device 4 and the insulating substrate 1 may be increased, the bonding strength between the electrode 3, the earth electrode 6, and the insulating substrate 1 may have a low bonding strength. Accordingly, it is possible to broaden a selectivity of material of the insulating substrate 1, the electrode 3, and the earth electrode 6. That is, in the embodiment a structure having a low bonding strength between the electrode 3 and the insulating substrate is properly used in which Ag plating surface of the binder resin on the electrode 3 is formed by using the PET film and PI film on the insulating substrate 1.

In the embodiment, the solder adhesive 20 (refer to FIG. 5) used for bonding the electrode 3 and the terminal 5, the solder adhesive 21 (refer to FIG. 5) used for bonding the earth electrode 6 and the earth terminal 8, and the solder adhesive 22 (refer to FIG. 5) used for bonding the surface 1a of the insulating substrate 1, which is the non-metal area 7b, and the earth terminal 8, all use the same adhesive (refer to FIG. 5). Accordingly, as mentioned below, the mounting structure of the electronic device in which the electronic device 4 and the insulating substrate 1 are strongly bonded, can be manufactured.

In addition, it is preferable that the solder layer 10, 11, 12 are the low melting-point solders. When the low melting-point solder is used, an inexpensive PET film can be used on the insulating substrate 1. Accordingly it is possible to manufacture at low cost, the mounting structure of the electronic device. In addition, it is possible to reduce the heating temperature by using the low melting-point solder. Accordingly, it is possible to reduce damage of the other parts caused by the heat other than the insulating substrate 1.

The thermosetting resin and thermoplastic are all used in the resin layer 13. In addition, in the embodiment, it is preferable that room-temperature curable resin and ultraviolet curable resin, and the like a used In addition, when a solder adhesive is used to mix the low melting-point solder and the thermosetting resin, the bonding of the low melting-pot solder and the bonding by the resin are performed simultaneously by one heating operation. Accordingly, as mentioned above, using the mixed solder adhesive is preferable. Epoxy resin, phenolic resin, melamine resin, urea resin, and polyester resin are used as the thermosetting resin. Since the above material have good characteristics of mechanical strength, medicine resistance, and bonding strength, the epoxy resin is preferably used. In addition, the binder resin included in the electrode 3 and the earth electrode 6 may be the same material as the material which forms the resin layer 13. That is, when the resin 13 is the epoxy resin and the binder resin included in the electrode 3 and the earth electrode 6 is also the epoxy resin, it is possible to properly enhance the bonding strength.

In the embodiment shown in FIGS. 1 and 2, the earth electrode 6 has the surrounding shape on the surface 1a of the insulating substrate 1. The non-metal area 7b is provided in which the surface of the surface of the insulating substrate 1 not having the earth electrode 6, is exposed in the center of the mounting area 7 of the electronic device 4. For example, the earth electrode 6 does not have the surrounding shape, but the earth electrode 6 is formed in a rectangular-shape, which is the same shape as the earth terminal 8. Accordingly, when the earth electrode 6 and the earth terminal 8 are soldered, an alignment in precision of the electronic device 4 to the insulating substrate 1 is decreased. Accordingly, the electrode 3 and the terminal 5 may not be properly bonded by the solder layer 10. Specifically, when the earth electrode 6 and the earth terminal 8 are strongly bonded by the solder layer 11 in the broad range of the center of the electronic device 4, the alignment precision is substantially decreased. Accordingly, the earth electrode 6 has the surrounding shape on the surface 1a of the insulating substrate 1 so that the solder-bonding is not performed in the center of the electronic device 4. Accordingly, it is preferable that the non-metal area 7b as a non-soldering area is provided in which the front surface of the insulating substrate 1 is exposed from the surrounding shape.

However, the non-metal area 7b and the earth terminal 8 are a bonded structure. When the earth teal 8 is not formed in the opposite position to the non-met area 7b, and a bonding area, which is the electronic device 4 and the opposed surface of the insulating substrate 1 by the solder adhesive 22 are the non-metal area, it is not preferable that the solder adhesive 22 is used between the non-metal areas. Since the solder particles included the solder adhesive 22 does not find a place to move, the solder particle is attached to an unpredictable position. Accordingly, to prevent the above-mentioned problem, it is required that the metal area (earth terminal 8) is provided in the position opposite the non-metal area 7b, the solder particle is agglomerated on the metal side, and then the solder layer 12 is formed as shown in FIG. 2.

In addition, in the embodiment shown in FIGS. 1 and 2, the earth terminal 8 is provided in the center of the back surface 4a of the electronic device 4 differently from the terminal 5 and tile electrode 3. The earth electrode 6 is provided in the center of the mounting area 7 of the insulating substrate 1 and the earth terminal 8, and the earth electrode 6 is bonded with the solder layer 11 interposed therebetween, but the earth terminal 8 and the earth electrode 6 may not function as an earth (hereinafter, metal films 6, 8). The metal film 6 need not be provided on the surface 1a of the insulating substrate 1 as the above mentioned. As shown in FIG. 2, the metal film 8 provided on the back surface 4a of the electronic device 4 and the surface 1a of the insulating substrate 1 are bonded to each other by the solder adhesive 22 (refer to FIG. 5). Accordingly, the solder layer 12 in which the solder particle is agglomerated is formed in contact with the metal film 8 and the surface 1a of the insulating substrate 1 are bonded to each other by the resin layer 13.

In addition, the metal film 6 is provided on the insulating substrate 1 side. At this time, the metal film 6 may not be formed in a surrounding shape shown in FIGS. 1 and 2. In the embodiment, the metal film 8 is not provided on the back surface 4a of the electronic device 4, and the metal film 6 and the back surface 4a (non-metal area) of the electronic device 4 are bonded to each other by the solder adhesive. That is, the solder layer 12 is formed in contact with the metal film 6 on the insulating substrate 1, and the metal film 6 and the back surface 4a of the electronic device 4 are bonded to each other by the resin layer 13. At this time, it is preferable that the metal film 6 formed on the surface 1a of the insulating substrate 1 has a close adhesion characteristic to the insulating substrate 1 than that of the electrode 3. Even when the metal film 6 and the insulating substrate 1 have a poor adhesion characteristics and the bonding strength between the metal film 6 and the back surface 4a of the electronic device 4 is greatly increased, the metal film 6 easily separates from the insulating substrate 1. Accordingly, it is not possible that the bonding strength between the electronic device 4 and the insulating substrate 1 can be substantially increased. Accordingly, when the bonding strength between the metal film 6 and the insulating substrate 1 increases less than that of the electrode 3 and the insulating substrate 1, it is preferable that the metal film 8 is provided on the back surface 4a of the electronic device 4. It is also preferably that a part of the surface 1a of the insulating substrate 1 opposed to the metal film 8 is exposed on the non-metal area 7b, and that the surface 1a of the insulating substrate 1 and the metal film 8 are bonded to each other by the solder adhesive. Accordingly, as mentioned above, it is possible that the bonding sigh between the insulating substrate 1 and the electric device 4 can be substantially increased. In addition, it is also preferable that the metal film 6 is provided on the insulating substrate 1 side so as to use the metal films 6, 8 as the earth.

Next, according to the embodiment, a method of manufacturing a mounting structure of the electronic device will be explained. FIGS. 4A and 5A are top plans view illustrating insulating substrate in a process of manufacturing. FIG. 4B is a cross sectional view illustrating the insulating substrate of FIG. 4A taken along Line 4B-4B by cutting in a thickness direction. FIG. 5B is a cross sectional view illustrating the insulating substrate of FIG. 5A taken along Line 5B-5B by cutting in the thickness direction.

In the process of FIGS. 4A and 4B, the wiring member 2 and the electrode 3 are formed with a pattern by using the screen print on the insulating substrate 1. As mentioned above, the insulating substrate 1 is formed by the PET film, and the like.

As shown in FIG. 4A, the electrode 3 is formed in four directions in the mounting area 7 of the electronic device 4. In the embodiment, the electrode 3 is formed differently from the wiring member 2, but the electrode 3 and the wiring member 2 are electrically connected to each other. The electrode 3 is formed of silver powder with a rectangle-shape, silver powder with the flake-shape, and Ag coated film having the binder resin. A content of the binder resin of the electrode 3 is less than that of the binders of the wiring member 2. Accordingly, the electrode 3 has better the solder wettability than that of the wiring member 2.

In the process shown in FIG. 4A, the earth electrode 6 is formed by the screen print in which the Ag coated film as the electrode 3 has the surrounding shape in the mounting area 7 on the insulating substrate 1, and the like. Then non-metal area 7b in which the surface 1a of the insulating substrate 1 is exposed in the surrounding shape.

Next, in a process shown in FIG. 5A, the solder adhesive 20 is applied onto the electrode 3, the solder 21 is applied onto the earth electrode 6, and the solder adhesive 22 is applied onto the surface 1a of the insulating substrate 1, which is the non-metal area 7b. The solder adhesives 21, 22 having a rectangular-shape are applied onto the earth electrode 6 and the surface 1a of the insulating substrate 1 at each position, respectively. The applying method is used, such as a metal master print, a screen print, a dispenser and the like. Among the method, the metal master print is preferably used.

In the embodiment, the solder adhesives 20, 21, 22 use the same adhesive respectively. Accordingly, it is possible to perform the applying process of the solder adhesives 20, 21, 22 simultaneously, thereby providing a simple manufacturing method.

The solder adhesives 20, 21, 22 containing the solder particles and the resin as major components. The solder is a low melting-point solder. It is preferable to select the low melting-point solder among SnBi, SnBiAg, SnZn, SnZnBi, SnZnIn, SnAgBiIn, SnAgCuBi, SnIn, SnBiIn. Herein, “a low melting-point solder” is a solder having the melting point is in the range of 60° C. to 200° C.

The resin uses the thermosetting resin and the thermoplastic resin, but preferably the thermosetting resin is used. The thermosetting resin uses the epoxy resin, the phenolic resin, the melamine resin, the urea resin, the polyester resin. Since the above material have good characteristics of mechanical strength, medicine resistance, and bonding strength, the epoxy resin is preferably used

The solder adhesives 20, 21, 22 are applied and then the QFN type electronic device is provided on the mounting area 7.

In addition, the heat treatment is performed. In the embodiment, it is not necessary that a heating temperature is set to a high temperature at the time of using the low melting-point solder as the solder particle. The heating temperature is adjusted in consideration of the low melting-point solder and the temperature of the thermally curing of the resin, and the like.

When the heat temperature is set in the range of 120° C. to 160° C. (preferably in the range of 150° C. to 160° C.), it is possible to be soldered by the low melting-point solder and be thermally cured of the resin.

By the heat treatment, the low melting-point solder included in each adhesives 20, 21, 22 is slowly melted and agglomerated. The solder layer 10 is formed by the agglomeration of the solder particle included in the solder adhesive 20 between the electrode 3 and the terminal 5, and the electrode 3 and the terminal 5 are electrically connected. In addition, the solder layer 11 is formed by the agglomeration of the solder adhesive included in the solder adhesive 21 between the earth electrode 6 and the earth terminal 8. Accordingly, the earth electrode 6 and the earth terminal 8 are electrically connected.

Meanwhile, in the surface 1a of the insulating substrate 1 exposed from the non-metal area 7b, since the surface 1a of the insulating substrate 1 is non-metal, as shown in FIG. 2, the solder particle included in the solder adhesive 22 is agglomerated on the earth terminal 8 and then the solder layer 12 is formed, which is in contact with the earth terminal 8.

The resin included in each solder adhesives 20, 21, 22 are divided from the solder particle by the heat treatment, then thermally cured, and the resin 13 is formed between the electronic device 4 and the insulating substrate 1 or around the electronic device 4.

In the embodiment, it is possible that the surface 1a of the insulating substrate 1 and the earth terminal 8 are properly bonded by the resin layer 13.

In the manufacturing method of the mounting structure of the electronic device, in the applying process of the solder adhesive of FIG. 5, since the same adhesives 20, 21, 22 are applied onto the electrode 3, the earth electrode 6, and the surface 1a of the insulating substrate 1, the applying process of the each solder adhesive is performed simultaneously (in the same process). Accordingly, when the each solder adhesive is heated simultaneously, the solder layer and the resin layer are formed at the same time. Accordingly, the heating process is performed in the same process. Accordingly, the applying process of the each solder adhesives 20, 21, 22 and the heating process (refer to the two process as a bonding process) are performed in the same process, thereby providing a simple manufacturing method.

Since the earth terminal 8 is provided in the electronic device 4 opposed to the surface 1a of the insulating substrate 1 from the non-metal area 7b in the electronic device 4, the solder particle of the solder adhesive 22 applied onto the surface 1a of the insulating substrate 1 may be agglomerated on the earth terminal 8. Accordingly, attachment of the solder particles at an unpredictable position is prevented.

In addition, in the embodiment, in the method of manufacturing the mounting structure of the electronic device, the surface 1a of the insulating substrate 1 exposed from the non-metal area 7b and the earth terminal 8 are properly bonded by the resin layer 13. Accordingly, it is possible that the bonding strength between the insulating substrate 1 and the electronic device 4 is increased.

### EXAMPLES

A mounting structure of the electronic device shown in FIGS. 1 and 2 was formed. Material using PET film (example 1) and material using PI film (example 2) is formed on the insulating substrate 1. In the process of FIG. 5A the solder adhesives 20, 21, 22 were all same, the solder adhesive contained a low melting pot solder of Sn—Bi and epoxy resin as major components.

Meanwhile, as the mounting structure of the electric device of comparative example, in the process of FIG. 5A, the solder adhesive 22 was not applied onto the surface 1a of the insulating substrate 1, which is the non-metal area 7b. However, in the comparative example, the solder adhesive 22 was applied onto the earth electrode 6 so as to apply the same content according to the example. The solder adhesive used in the comparative example was the same as the solder adhesive used in the example. In addition, in comparative example 1, the PET film is used on the insulating substrate 1 and the PI film is used in comparative example 2. As above-mentioned comparative examples, the solder adhesive 22 was not applied onto the non-metal are 7b. However, the other conditions were all the same as the example.

In the experiment, a bonding strength was a maximum strength by measuring when a side of the mounted electronic device is pushed at the rate of 5 mm/min.

The bonding strength of the example 1 was 115 N, the bonding strength of the example 2 was 91 N, the bonding strength of the comparative example 1 was 85 N, and the bonding strength of the comparative example 2 was 74 N.

What is claimed is:

1. An electronic device mounting structure comprising:
an insulating subs having an electrode provided on a front surface thereof; and
an electronic device having a terminal connected electrically to the electrode;
wherein a first metal area is formed at a position on one opposed surface of the insulating substrate and the electronic device opposed to a non-metal area on the other opposed surface;
the first metal area and the non-metal area are bonded to each other by a solder adhesive containing solder particles and a resin as major components; and
the solder particles are agglomerated on the first metal area so as to form a solder layer, and the resin bonds the fit metal area and the non-metal area to each other.

2. The electronic deice mounting structure according to claim 1, wherein the electrode and the terminal are soldered using solder adhesive used for bonding the first metal area and the non-metal area to each other.

3. The electronic device mounting structure according to claim 1, wherein the it metal area is formed on a back surface of the electronic device, and the non-metal area is a front surface of the insulating substrate.

4. The electronic device mounting structure according to claim 3, wherein a second metal area is formed on a part of the front surface of the insulting substrate opposed to the first metal area formed on the back surface of the electric device;
the front surface of the insulating substrate as the non-metal area is exposed from the other opposed area, and
the first metal area and the second metal area are soldered by the same adhesive used for bonding the first metal area and the front surface of the insulating substrate.

5. The electronic device mounting structure according to claim 4, wherein the second metal area has a surrounding shape, the front surface of the insulating substrate as the non-metal area is exposed in the surrounding shape, and the front surface of the insulating substrate in the surrounding shape and the first metal area are bonded to each other by the solder adhesive.

6. A method of manufacturing an electronic device mounting structure comprising:
an insulating substrate having an electrode provided on a front surface thereof; and
an electronic device having a terminal electrically connected to the electrode in which the electronic device is mounted on the insulating substrate;
wherein a first metal area is formed at a position on one opposed surface of the insulating substrate and the electronic device opposed to a non-metal area on the other opposed surface,
wherein the electrode and the terminal are soldered by a solder adhesive containing solder particles and a resin as major components and being the same as the solder adhesive, and
wherein the non-metal area and the first metal area are bonded to each other by the resin contained in the solder adhesive by the use of the same process as bonding the electrode and the terminal.

7. The method according to claim 6, wherein the resin is a thermosetting resin, the solder adhesive is applied and heated to melt the solder particles, the electrode and the terminal are soldered, the resin is thermally cured to bond the non-metal area and the first metal area to each other.

8. The method according to claim 6, wherein the first metal area is formed in a back surface of the electronic device, the front surface of the insulating substrate is the non-metal area, the solder adhesive is applied to the electrode and the front surface of the insulating substrate, and then the electronic device is bonded to the insulating substrate with the solder adhesive.

9. The method according to claim 8, wherein a second metal area is formed in a part of the front surface of the insulating substrate opposed to the first metal area formed on the back surface of the electronic device;
the front surface of the insulating substrate as the non-metal area is exposed from the other opposed area;
the solder adhesive is applied onto the electrode, the second metal area, and the front surface of the insulating substrate, and
the electronic device is bonded onto the insulating substrate with the solder adhesive.

10. The method according to claim 9, wherein the second metal area has a surrounding shape, the front spice of the insulating substrate as the non-metal area is exposed in the surrounding shape, and the front surface of the insulating substrate and the first metal area are bonded to each other in the surrounding by the solder adhesive.
